(19) United States
(12) Patent Application Publication
(10) Pub. No.: US 2026/0180564 A1
(43) Pub. Date: Jun. 25, 2026

(54) DATA INPUT OUTPUT CIRCUIT AND SEMICONDUCTOR DEVICE INCLUDING THE SAME

(71) Applicant: Samsung Electronics Co., Ltd., Suwon-si (KR)

(72) Inventors: Jindo Byun, Suwon-si (KR); Sangyun Kim, Suwon-si (KR); Kyoungtae Kang, Suwon-si (KR); Youngdon Choi, Suwon-si (KR)

(21) Appl. No.: 19/337,518

(22) Filed: Sep. 23, 2025

(30) Foreign Application Priority Data
Dec. 23, 2024 (KR) 10-2024-0194343

(51) Int. Cl. H03K 5/01; H03H 7/00; H03K 5/00

(52) U.S. Cl. CPC H03K 5/01; H03H 7/00; H03K 2005/00013

(57) ABSTRACT

An example semiconductor device includes an input/output pad connected to a first node, a main transmitter configured to provide a main data signal to the input/output pad via the first node, an equalization transmitter configured to provide an equalization data signal to the input/output pad through the first node, and a resonant circuit including a first capacitor and a first inductor coupled in series between the first node and the equalization transmitter.

### CROSS-REFERENCE TO RELATED APPLICATION

This application claims priority to and the benefit of Korean Patent Application No. 10-2024-0194343 filed with the Korean Intellectual Property Office on Dec. 23, 2024, the entire contents of which are incorporated herein by reference.

### BACKGROUND

Semiconductor devices are connected to external devices through transmission lines. When a data signal is transmitted through the transmission line, a transmission characteristic according to the frequency of the transmission line has a characteristic of a low-pass filter, so high-frequency data signals can be attenuated. To compensate for the attenuated high-frequency components, a pre-emphasis scheme that boosts the gain of the high-frequency components and a de-emphasis scheme that reduces the gain of the low-frequency components are used.

### SUMMARY

The present disclosure relates to a data input/output circuit that equalizes a data signal by using a resonant circuit and a semiconductor device including the same.

In general, according to some aspects, a semiconductor device includes an input/output pad connected to a first node, a main transmitter configured to provide a main data signal to the input/output pad via the first node, an equalization transmitter configured to provide an equalization data signal to the input/output pad through the first node, and a resonant circuit including a first capacitor and a first inductor coupled in series between the first node and the equalization transmitter.

In general, according to some aspects, a semiconductor circuit includes a main transmitter configured to provide a main data signal to a first node, an equalization transmitter configured to output an equalization data signal, a resonant circuit configured to receive the equalization data signal and output, via resonance, a resonant data signal to the first node, and an Input/output pad connected to the first node and configured to output the main data signal and the resonant data signal to an outside.

In general, according to some aspects, a semiconductor device includes a substrate, a ferry structure positioned on the substrate and including a main transmitter, an equalization transmitter, and a capacitor connected to the equalization transmitter, a cell structure positioned on the ferry structure and including memory cells, a wire structure positioned on the cell structure and including an inductor wire connected to the capacitor and the main transmitter; and an input/output pad positioned on the wire structure and connected to the inductor wire.

### BRIEF DESCRIPTION OF THE DRAWINGS

FIG. 1 is a view illustrating an example of a semiconductor memory device including a data input/output circuit.

FIG. 2 is a view explaining an example of a data input/output circuit.

FIG. 3 is a view illustrating an example of a main transmitter and an example of an equalization transmitter.

FIG. 4 is a view illustrating an example of a data input/output circuit including a second inductor.

FIG. 5 is a view illustrating an example of a data input/output circuit including a delay circuit and a receiver.

FIG. 6 is a view illustrating an example of a data input/output circuit.

FIG. 7 is a view explaining an example of a resonant circuit.

FIG. 8 is a view for explaining an example of an output data signal.

FIG. 9 is a view for explaining an example of a delay data signal.

FIG. 10 is a top plan view illustrating an example of an inductor wire.

FIG. 11 is a cross-sectional view illustrating an example of a semiconductor memory device including an inductor wire.

FIG. 12 is a view illustrating an example of a connection relationship of a main transmitter, an equalization transmitter, a receiver, and an inductor wire.

FIG. 13 is a view illustrating an example of a connection relationship of a main transmitter, an equalization transmitter, a receiver, and an inductor wire.

FIG. 14 is a view to explain an example of an impedance according to a frequency.

FIG. 15 is a view to explain an example of a size of an output data signal according to a frequency.

FIG. 16 and FIG. 17 are views for explaining an example of a peak value of an output data signal.

FIG. 18 is a view to explain an example of an eye diagram of an output data signal.

FIG. 19 is a view explaining an example of a memory system.

FIG. 20 is a view for explaining an example of a communication apparatus.

FIG. 21 is a view illustrating an example of a system on chip.

### DETAILED DESCRIPTION

The present disclosure will be described more fully hereinafter with reference to the accompanying drawings, in which implementations of the disclosure are shown. As those skilled in the art would realize, the described implementations may be modified in various different ways, all without departing from the spirit or scope of the present disclosure.

To clearly describe the implementations of the present disclosure, parts not related to the description are omitted, and like reference numerals designate like constituent elements throughout the specification.

In the drawings, the sizes and thicknesses of the components are merely shown for convenience of explanation, and therefore the present disclosure is not necessarily limited to the illustrations described and shown herein. In the drawings, the thickness of layers, films, panels, regions, etc., are exaggerated for clarity. In the drawings, for better understanding and ease of description, the thickness of some layers and areas is exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

Further, in the specification, the phrase “in a plan view” means when an object portion is viewed from above, and the phrase “in a cross-section” means when a cross-section taken by vertically cutting an object portion is viewed from the side.

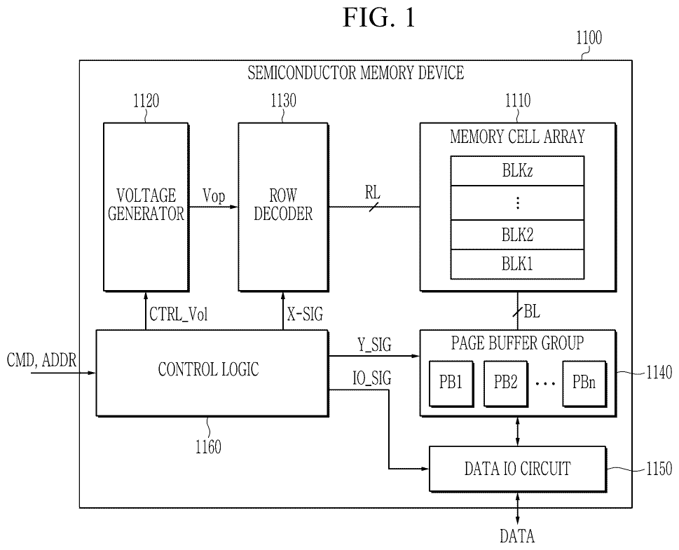

FIG. 1 is a view illustrating an example of a semiconductor memory device including a data input/output circuit.

Referring to FIG. 1, a semiconductor memory device 1100 may include a memory cell array 1110, a voltage generator 1120, a row decoder 1130, a page buffer group 1140, a data input/output circuit 1150, and a control logic 1160. In some implementations, the semiconductor memory device 1100 may be a non-volatile memory device. In some implementations, the semiconductor memory device 1100 may be a NAND flash memory.

In some implementations, the memory cell array 1110 may include a plurality of memory blocks BLK1 to BLKz. The plurality of memory blocks BLK1 to BLKz may be connected to the row decoder 1130 via row lines RL. The plurality of memory blocks BLK1 to BLKz may be connected to the page buffer group 1140 via bit lines BL. The plurality of memory blocks BLK1 to BLKz may include a plurality of memory cells, respectively. In some implementations, the plurality of memory cells may be non-volatile memory cells.

In some implementations, the voltage generator 1120 may generate operating voltages Vop using an external power voltage supplied to the semiconductor memory device 1100. The voltage generator 1120 may operate in response to the control of the control logic 1160.

In some implementations, the voltage generator 1120 may generate operating voltages Vop used for program operations, read operations, and erase operations. For example, the voltage generator 1120 may generate a program voltage, a pass voltage, a read voltage, and an erase voltage. The operating voltages Vop may be supplied to the memory cell array 1110 by the row decoder 1130.

In some implementations, the row decoder 1130 may be connected to the memory cell array 1110 via row lines RL. The row lines RL may include string selection lines, word lines, and ground selection lines.

In some implementations, the row decoder 1130 may operate in response to the control of the control logic 1160. The row decoder 1130 may receive a row signal X_SIG from the control logic 1160. In some implementations, the row decoder 1130 may select at least one word line from the plurality of word lines based on the row signal X_SIG, and apply the operating voltages Vop provided from the voltage generator 1120 to at least one word line.

In some implementations, the row decoder 1130 may apply the program voltage to the selected word line among the plurality of word lines during a program operation and apply a pass voltage at a level lower than the program voltage to the unselected word lines. The row decoder 1130 may apply a verification voltage to the selected word lines and a verification pass voltage of a higher level than the verification voltage to the unselected word lines during a program verification operation.

In some implementations, the row decoder 1130 may apply a read voltage to the selected word line during a read operation and apply a read pass voltage of a level higher than the read voltage to the unselected word lines.

In some implementations, the page buffer group 1140 may include a plurality of page buffers PB1 to PBn. The plurality of page buffers PB1 to PBn may be connected to the plurality of memory cells included in the memory cell array 1110 via the bit lines BL, respectively. The plurality of page buffers PB1 to PBn may operate in response to the control of the control logic 1160. The plurality of page buffers PB1 to PBn may select at least one bit line among the bit lines BL based on a column signal Y_SIG received from the control logic 1160.

In some implementations, the plurality of page buffers PB1 to PBn may communicate a data DATA with a data input/output circuit 1150. The plurality of page buffers PB1 to PBn may receive the data DATA from the data input/output circuit 1150 during the program operation. The plurality of page buffers PB1 to PBn may provide the data DATA to the data input/output circuit 1150 during the read operation.

In some implementations, the plurality of page buffers PB1 to PBn may transmit a data received from the outside to the plurality of memory cells of the memory cell array 1110 through the bit lines BL during the program operation. The plurality of memory cells may be programmed according to the received data. The plurality of page buffers PB1 to PBn may sense the data stored in the plurality of memory cells through the bit lines BL during the program verification operation.

In some implementations, the plurality of page buffers PB1 to PBn may sense the data stored in the memory cells through bit lines BL during the read operation, and store the sensed data in the plurality of page buffers PB1 to PBn.

In some implementations, the data input/output circuit 1150 may be connected to the page buffer group 1140 and the control logic 1160. The data input/output circuit 1150 may provide the data received from the outside to the page buffer group 1140. The data input/output circuit 1150 may output the data sensed by the page buffer group 1140 to the outside. The data input/output circuit 1150 may transmit and receive the data DATA in response to the control of the control logic 1160.

In some implementations, control logic 1160 may be connected to the voltage generator 1120, the row decoder 1130, the page buffer group 1140, and the data input/output circuit 1150.

In some implementations, the control logic 1160 may control the overall operation of the semiconductor memory device 1100. The control logic 1160 may respond to commands received from the outside and control the voltage generator 1120, the row decoder 1130, and the page buffer group 1140 to perform the operations corresponding to the commands. In some implementations, the control logic 1160 may provide an input/output signals IO_SIG to the data input/output circuit 1150 to control the operation of the data input/output circuit 1150.

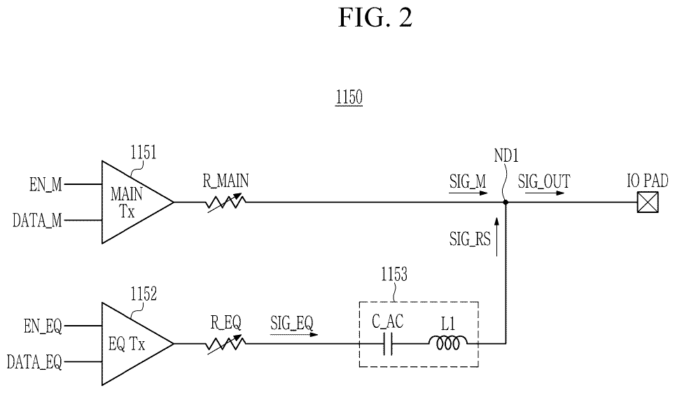

FIG. 2 is a view explaining an example of a data input/output circuit.

Referring to FIG. 2, the data input/output circuit 1150 may include a main transmitter 1151, an equalization transmitter 1152, a resonant circuit 1153, an input/output pad IO PAD, a main resistor R_MAIN, and an equalization resistor R_EQ.

In some implementations, the main transmitter 1151 may be a voltage mode driver. In some implementations, the main transmitter 1151 may be connected to the main resistor R_MAIN. In some implementations, the main transmitter 1151 may operate in response to a main enable signal EN_M. In some implementations, the main enable signal EN_M may be one of the input/output signals IO_SIG received from control logic 1160.

In some implementations, the main transmitter 1151 may receive the main data DATA_M and provide the main data signal SIG_M to the first node ND1 based on the main data DATA_M. In some implementations, the main data DATA_M may correspond to the data received from the page buffer group 1140. In some implementations, the main data DATA_M may correspond to the data sensed by the page buffer group 1140 from the plurality of memory cells. In some implementations, the main data signal SIG_M may be a non return to zero (NRZ) signal or a pulse amplitude modulation-n level (PAM-N) signal.

In some implementations, the main resistor R_MAIN may be connected between the main transmitter 1151 and the first node ND1. In some implementations, the main resistor R_MAIN may be a variable resistor.

In some implementations, the equalization transmitter 1152 may be connected to the equalization resistor R_EQ. In some implementations, the equalization transmitter 1152 may operate in response to an equalization enable signal EN_EQ. In some implementations, the equalization enable signal EN_EQ may be one of the input/output signals IO_SIG received from the control logic 1160.

In some implementations, equalization transmitter 1152 may be a voltage mode driver. In some implementations, the equalization transmitter 1152 may receive an equalization data DATA_EQ and output an equalization data signal SIG_EQ based on the equalization data DATA_EQ. The equalization data signal SIG_EQ may be provided to the resonant circuit 1153. In some implementations, the equalization data DATA_EQ may be one of the input/output signals IO_SIG received from the control logic 1160.

In some implementations, the equalization transmitter 1152 may provide a high level equalization data signal SIG_EQ to the resonant circuit 1153 in response to the rising edge of the main data signal SIG_M. In some implementations, the equalization transmitter 1152 may provide a low level equalization data signal SIG_EQ to the resonant circuit 1153 in response to the falling edge of the main data signal SIG_M. In some implementations, the low level equalization data signal SIG_EQ may be a negative level signal.

In some implementations, the equalizing resistor R_EQ may be connected between the equalization transmitter 1152 and the resonant circuit 1153. In some implementations, the equalizing resistor R_EQ may be a variable resistor.

In some implementations, the resonant circuit 1153 may be connected between the equalizing resistor R_EQ and the first node ND1. In some implementations, the resonant circuit 1153 may include a capacitor C_AC and a first inductor L1 coupled in series between the equalizing resistor R_EQ and the first node ND1. In some implementations, the capacitor C_AC may be a variable capacitor.

In some implementations, the resonant circuit 1153 may receive the equalization data signal SIG_EQ and output, via resonance, the resonant data signal SIG_RS to the first node ND1. In some implementations, the resonant data signal SIG_RS may be a resonant signal of the equalization data signal SIG_EQ. The resonant frequency may be determined based on the capacitance of the capacitor C_AC and the inductance of the first inductor L1. In some implementations, the frequency of the equalization data signal SIG_EQ may be substantially the same as the resonant frequency of the resonant circuit 1153. In some implementations, the substantial equality may mean that the frequency of the equalization data signal SIG_EQ is a frequency within the band pass bandwidth of the resonant circuit. In some implementations, the frequency of the equalization data signal SIG_EQ may be a frequency included within a 3 dB bandwidth of the bandpass bandwidth of the resonant circuit.

In some implementations, the magnitude of the high level resonant data signal SIG_RS may be larger than the high level equalization data signal SIG_EQ. In some implementations, the magnitude of the low level resonant data signal SIG_RS may be smaller than the low level equalization data signal SIG_EQ.

In some implementations, the input/output pad IO PAD may be connected to the first node ND1. In some implementations, the input/output pad IO PAD receives an output data signal SIG_OUT, which is the combination of the main data signal SIG_M and the resonant data signal SIG_RS, and may output the output data signal SIG_OUT to the outside.

In some implementations, the output data signal SIG_OUT may be a signal that is the combination of the main data signal SIG_M and the resonant data signal SIG_RS at the rising edge of the main data signal SIG_M. In some implementations, at the rising edge, the magnitude of the output data signal SIG_OUT may be larger than the magnitude of the main data signal SIG_M.

In some implementations, the output data signal SIG_OUT may be a signal that is a combination of the main data signal SIG_M and the resonant data signal SIG_RS at the falling edge of the main data signal SIG_M. In some implementations, at the falling edge, the magnitude of the output data signal SIG_OUT may be smaller than the magnitude of the main data signal SIG_M.

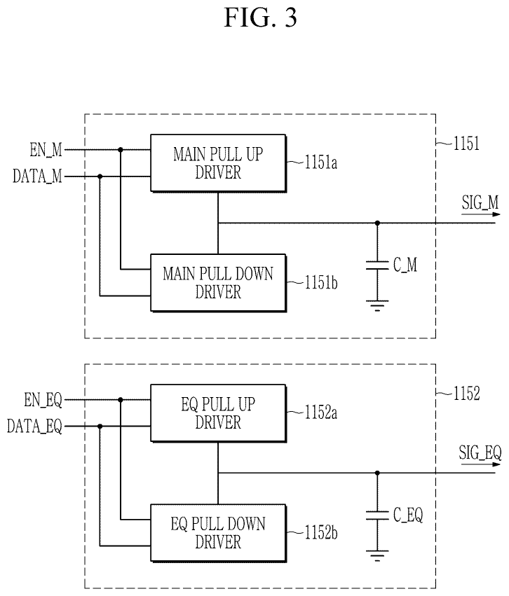

FIG. 3 is a view illustrating an example of a main transmitter and an example of an equalization transmitter.

Referring to FIG. 3, the main transmitter 1151 may include a main pull-up driver 1151a, a main pull-down driver 1151b, and a main capacitor C_M. In some implementations, the main pull-up driver 1151a and the main pull-down driver 1151b may receive the main enable signal EN_M and the main data DATA_M.

In some implementations, the main pull-up driver 1151a may output the high level main data signal SIG_M in response to the main enable signal EN_M. In some implementations, the main pull-down driver 1151b may output the low level main data signal SIG_M in response to the main enable signal EN_M.

In some implementations, the main capacitor C_M may be connected between the main pull-up driver 1151a and the main pull-down driver 1151b. In some implementations, the main capacitor C_M may be charged with a charge corresponding to the magnitude of the main data signal SIG_M. In some implementations, the capacitance of the capacitor C_AC included in the resonant circuit 1153 of FIG. 2 may be larger than the capacitance of the main capacitor C_M.

In some implementations, the equalization transmitter 1152 may include an equalization pull-up driver 1152a, an equalization pull-down driver 1152b, and an equalization capacitor C_EQ. In some implementations, the equalization pull-up driver 1152a and the equalization pull-down driver 1152b may receive the equalization enable signal EN_EQ and the equalization data DATA_EQ.

In some implementations, the equalization pull-up driver 1152a may output the high level equalization data signal SIG_EQ in response to the equalization enable signal EN_EQ. In some implementations, the equalization pull-down driver 1152b may output the low level equalization data signal SIG_EQ in response to the equalization enable signal EN_EQ. In some implementations, the low level equalization data signal SIG_EQ may correspond to a negative level.

In some implementations, the equalization capacitor C_EQ may be connected between the equalization pull-up driver 1152a and the equalization pull-down driver 1152b. In some implementations, the equalization capacitor C_EQ may be charged with a charge corresponding to the magnitude of the equalization data signal SIG_EQ. In some implementations, the capacitance of the capacitor C_AC included in the resonant circuit 1153 of FIG. 2 may be larger than the capacitance of the equalization capacitor C_EQ.

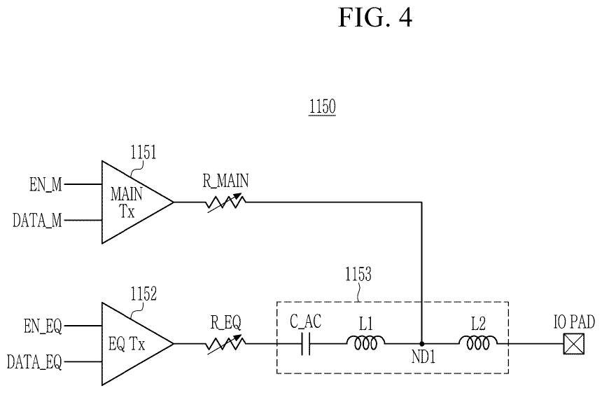

FIG. 4 is a view illustrating an example of a data input/output circuit including a second inductor.

Referring to FIG. 4, the resonant circuit 1153 may include a capacitor C_AC, a first inductor L1, and a second inductor L2 coupled in series between the equalizing resistor R_EQ and the input/output pad IO PAD. In some implementations, the second inductor L2 may be connected between the first node ND1 and the input/output pad IO PAD. In some implementations, the resonant circuit 1153 may include a T-Coil inductor. In some implementations, the T-Coil inductor may include a first inductor L1 connected between the first node ND1 and the capacitor C_AC, which are connected to the main transmitter 1151 and the main resistor R_MAIN, and a second inductor L2 connected between the first node ND1 and the input/output pad IO PAD.

In some implementations, the main transmitter 1151 may output the main data signal SIG_M based on the main data DATA_M. The main data signal SIG_M may be provided to the input/output pad IO PAD through the first node ND1.

In some implementations, the equalization transmitter 1152 may output the equalization data signal SIG_EQ based on the equalization data DATA_EQ. In some implementations, the equalization data signal SIG_EQ may be provided to the resonant circuit 1153 through the equalization resistor R_EQ.

In some implementations, the resonant circuit 1153 may receive the equalization data signal SIG_EQ and output, via resonance, the resonant data signal SIG_RS to the input/output pad IO PAD. The resonant frequency may be determined based on the capacitance of the capacitor C_AC, and the inductance of the first inductor L1 and the second inductor L2. In some implementations, the frequency of the equalization data signal SIG_EQ may be substantially the same as the resonant frequency of the resonant circuit 1153.

In some implementations, the input/output pad IO PAD may output an output data signal SIG_OUT, which is a combination of the main data signal SIG_M and the resonant data signal SIG_RS, to the outside.

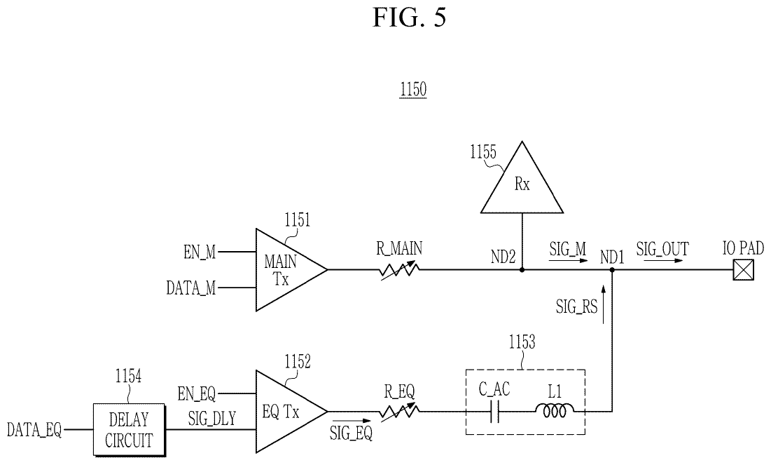

FIG. 5 is a view illustrating an example of a data input/output circuit including a delay circuit and a receiver.

Referring to FIG. 5, the data input/output circuit 1150 may include a main transmitter 1151, an equalization transmitter 1152, a resonant circuit 1153, a delay circuit 1154, a receiver 1155, a main resistor R_MAIN, an equalization resistor R_EQ, and an input/output pad IO PAD. In some implementations, the resonant circuit 1153 may include a capacitor C_AC and a first inductor L1.

In some implementations, the delay circuit 1154 may be connected to the equalization transmitter 1152. In some implementations, the delay circuit 1154 may receive the equalization data DATA_EQ and provide a delay data signal SIG_DLY to the equalization transmitter 1152 based on the equalization data DATA_EQ. In some implementations, the delay data signal SIG_DLY may be a signal that delays the transition point of the level of the equalization data DATA_EQ so that the level of equalization data DATA_EQ transitions high or low at the rising edge or falling edge of the main data signal.

In some implementations, the delay circuit 1154 may be a variable delay circuit. In some implementations, the delay circuit 1154 may provide the delay data signal SIG_DLY that delays the level of equalization data DATA_EQ, which transitions from low level to high level at a time later than the rising edge of the main data signal SIG_M, to transition from low level to high level at the rising edge of the main data signal SIG_M, to the equalization transmitter 1152.

In some implementations, the delay circuit 1154 may provide the delay data signal SIG_DLY that delays the level of equalization data DATA_EQ, which transitions from a low level to a high level before the rising edge of the main data signal SIG_M, to transition from a low level to a high level at the rising edge of the main data signal SIG_M, to the equalization transmitter 1152.

In some implementations, the equalization transmitter 1152 may output the equalization data signal SIG_EQ based on the delay data signal SIG_DLY. In some implementations, the equalization data signal SIG_EQ may be activated to a high level or a low level at the rising edge or falling edge of the main data signal SIG_M.

In some implementations, the resonant circuit 1153 may receive the equalization data signal SIG_EQ and output, via resonance, the resonant data signal SIG_RS to the first node ND1, and the main transmitter 1151 may provide the main data signal SIG_M to the first node ND1. In some implementations, the input/output pad IO PAD may output an output data signal SIG_OUT, which is a combination of the main data signal SIG_M and the resonant data signal SIG_RS received from the first node ND1, to the outside.

In some implementations, the receiver 1155 may receive a data provided from the outside to input/output pad IO PAD. In some implementations, the receiver 1155 may be connected to the second node ND2 between the first node ND1 and the main resistor R_MAIN.

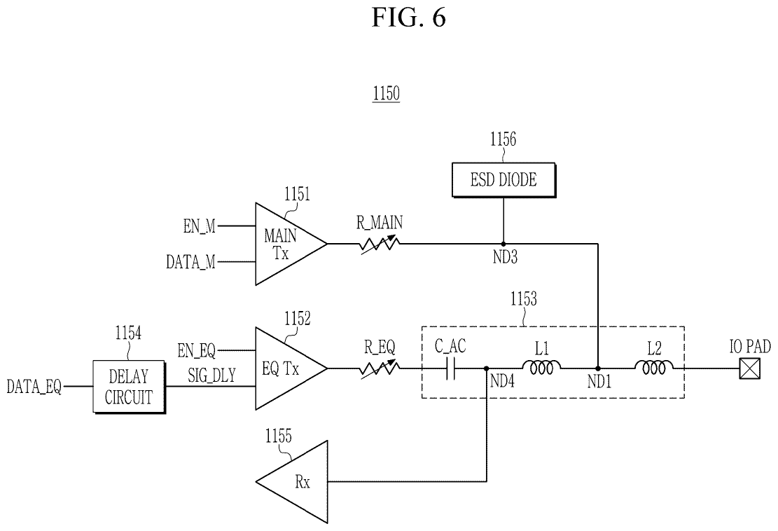

FIG. 6 is a view illustrating an example of a data input/output circuit.

In FIG. 6, any content that overlaps that of FIG. 2 and FIG. 5 is omitted. Referring to FIG. 6, the data input/output circuit 1150 may include a main transmitter 1151, an equalization transmitter 1152, a resonant circuit 1153, a delay circuit 1154, a receiver 1155, an electro static discharge (ESD) diode 1156, a main resistor R_MAIN, an equalization resistor R_EQ, and an input/output pad IO PAD.

In some implementations, the resonant circuit 1153 may include a capacitor C_AC, a first inductor L1, and a second inductor L2. In some implementations, the second inductor L2 may be connected between the first node ND1 and the input/output pad IO PAD.

In some implementations, the receiver 1155 may be connected to the fourth node ND4 between the capacitor C_AC and the first inductor L1.

In some implementations, the ESD diode 1156 may be a diode for protecting the static electricity discharge. In some implementations, the ESD diode 1156 may be connected to the third node ND3 between the main resistor R_MAIN and the first node ND1.

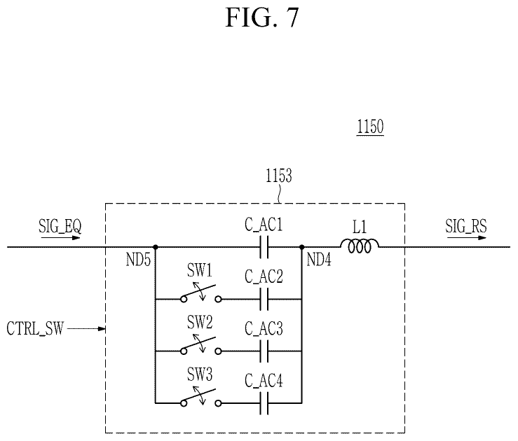

FIG. 7 is a view explaining an example of a resonant circuit.

Referring to FIG. 7, the resonant circuit 1153 may include a plurality of capacitors, a plurality of switches, and a first inductor L1. In some implementations, the resonant circuit 1153 may include a first capacitor C_AC1a, a second capacitor C_AC2, a third capacitor C_AC3, and a fourth capacitor C_AC4. In some implementations, the first to fourth capacitors C_AC1 to C_AC4 may be connected in parallel between the fourth node ND4 and the fifth node ND5. In some implementations, the resonant circuit 1153 may include a first switch SW1, a second switch SW2, and a third switch SW3.

In some implementations, the second to fourth capacitors C_AC2 to C_AC4 may be connected to the first to third switches SW1 to SW3 respectively. In some implementations, the first to third switches SW1 and SW3 may be opened or closed depending on the switch control signal CTRL_SW. In some implementations, the switch control signal CTRL_SW may be one of the input/output signals IO_SIG received from the control logic 1160.

In some implementations, the resonant frequency of the resonant circuit 1153 may be changed depending on the number of the capacitors connected in parallel. In some implementations, the number of the capacitors connected in parallel may be changed depending on the number of the open or closed switches.

In some implementations, when the first switch SW1 is closed and the second switch SW2 and the third switch SW3 are opened, the first capacitor C_AC1 and the second capacitor C_AC2 may be connected in parallel. In some implementations, when the first to third switches SW1 to SW3 are closed, the first to fourth capacitors C_AC1 to C_AC4 may be connected in parallel.

In some implementations, the resonant frequency of the resonant circuit in which the first switch SW1 is closed and the second switch SW2 and the third switch SW3 are opened may be greater than the resonant frequency of the resonant circuit 1153 in which the first to fourth switches SW1 to SW4 are closed.

In some implementations, the resonant frequency of the resonant circuit 1153 may be adjusted via first to third switches SW1 to SW3 to correspond to the frequency of the equalization data signal.

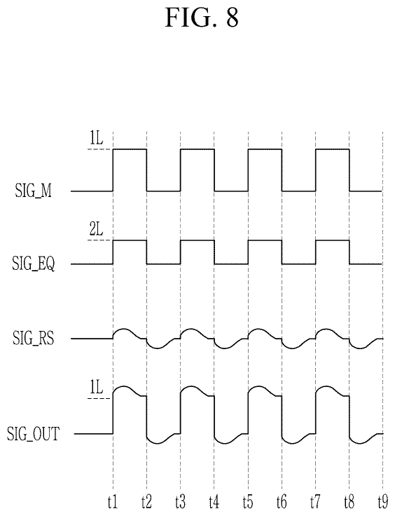

FIG. 8 is a view for explaining an example of an output data signal.

Referring to FIG. 8, at a time t1, the main transmitter 1151 may transition the main data signal SIG_M from a low level to a high level. In some implementations, the magnitude of the main data signal SIG_M may correspond to the magnitude of the voltage. In some implementations, at a time t1, the magnitude of the main data signal SIG_M may be a first level 1L. In some implementations, at a time t2, the main transmitter 1151 may transition the main data signal SIG_M from a high level to a low level.

In some implementations, at the time t1, the equalization transmitter 1152 may transition the equalization data signal SIG_EQ from a low level to a high level in response to the rising edge of the main data signal SIG_M. In some implementations, the magnitude of the transition from a low level to a high level may be a second level 2L. In some implementations, the second level L2 may be less than or equal to the first level L1.

In some implementations, at the time t2, the equalization transmitter 1152 may transition the equalization data signal SIG_EQ from a high level to a low level in response to the falling edge of the main data signal SIG_M. In some implementations, the magnitude of the transition from high level to a low level may be a second level 2L.

In some implementations, during the period t1 to t2, the resonant circuit 1153 may output a resonant data signal SIG_RS that resonates the equalization data signal SIG_EQ. In some implementations, the resonant circuit 1153 may output the resonant data signal SIG_RS in response to the rising edge or the falling edge of the main data signal SIG_M.

In some implementations, in the period t1 to t2, the resonant circuit 1153 may output the resonant data signal SIG_RS in which the DC component is removed from the high level equalization data signal SIG_EQ and the AC component remains. In some implementations, in the period t1 to t2, the resonant circuit 1153 may output the resonant data signal SIG_RS of the lower level than the equalization data signal SIG_EQ of the high level.

In some implementations, in the period t2 to t3, the resonant circuit 1153 may output the resonant data signal SIG_RS that resonates the equalization data signal SIG_EQ of the low level. In some implementations, in the period t2 to t3, the resonant circuit 1153 may output the resonant data signal SIG_RS in which the DC component is removed from the low level equalization data signal SIG_EQ and the AC component remains.

In some implementations, in the period t2 to t3, the level of the resonant data signal SIG_RS may be lower than the level of the equalization data signal SIG_EQ. In some implementations, in the period t2 to t3, the level of the resonant data signal SIG_RS may be a negative level lower than the low level. In some implementations, the input/output pad IO PAD may output the output data signal SIG_OUT of a level that is the sum of the main data signal SIG_M and the resonant data signal SIG_RS. In some implementations, during the period t1 to t2, the input/output pad IO PAD may output the output data signal SIG_OUT of a higher level than the main data signal SIG_M.

In some implementations, during the period t2 to t3, the input/output pad IO PAD may output the output data signal SIG_OUT of a lower level than the main data signal SIG_M. In some implementations, during the period t2 to t3, the input/output pad IO PAD may output the output data signal SIG_OUT of the negative level.

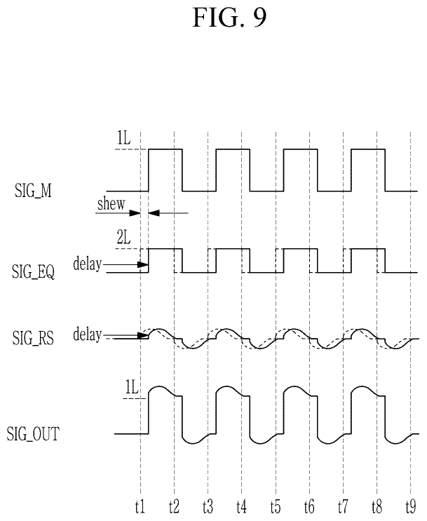

FIG. 9 is a view for explaining an example of a delayed data signal.

Referring to FIG. 9, the main transmitter 1151 may transition the main data signal SIG_M from a low level to a high level at a time later than the time t1, and may transition the main data signal SIG_M from a high level to a low level at a time later than the time t2.

In some implementations, the equalization transmitter 1152 may transition the equalization data signal SIG_EQ from a low level to a high level at the time t1, and may transition the equalization data signal SIG_EQ from a high level to a low level at the time t2.

In some implementations, the time when the equalization data signal SIG_EQ transitions from a low level to a high level may be earlier than the time when the main data signal SIG_M transitions from a low level to a high level. The difference between the time when the equalization data signal SIG_EQ transitions from a low level to a high level and the time when the main data signal SIG_M transitions from a low level to a high level may correspond to a skew.

In some implementations, the delay circuit 1154 may provide the delay data signal SIG_DLY to the equalization transmitter 1152 based on the equalization data DATA_EQ. In some implementations, the delay circuit 1154 may provide the delay data signal SIG_DLY to the equalization transmitter 1152, which delays the time at which the level of the equalization data DATA_EQ changes so that the level of the equalization data DATA_EQ changes at the rising edge or falling edge of the main data signal SIG_M. In some implementations, the delay circuit 1154 may provide the delay data signal SIG_DLY to the equalization transmitter 1152 so that the level of the equalization data signal SIG_EQ transitions from a low level to a high level at the rising edge of the main data signal SIG_M.

In some implementations, the equalization transmitter 1152 may output the equalization data signal SIG_EQ based on the delay data signal SIG_DLY. In some implementations, the level of the equalization data signal SIG_EQ output based on the delay data signal SIG_DLY may transition to a high level at the rising edge of the main data signal SIG_M.

In some implementations, the resonant circuit 1153 may output the resonant data signal SIG_RS based on the equalization data signal SIG_EQ. In some implementations, the level of the resonant data signal SIG_RS may increase at the rising edge of the main data signal SIG_M. In some implementations, the delay circuit 1154 may provide the delay data signal SIG_DLY to the equalization transmitter 1152 so that the level of the equalization data signal SIG_EQ transitions from a high level to a low level at the falling edge of the main data signal SIG_M.

In some implementations, the equalization transmitter 1152 may output the equalization data signal SIG_EQ based on the delay data signal SIG_DLY. In some implementations, the level of the equalization data signal SIG_EQ output based on the delay data signal SIG_DLY may transition to a low level at the falling edge of the main data signal SIG_M.

In some implementations, the resonant circuit 1153 may output the resonant data signal SIG_RS based on the equalization data signal SIG_EQ. In some implementations, the level of the resonant data signal SIG_RS may decrease to a negative level at the falling edge of the main data signal SIG_M.

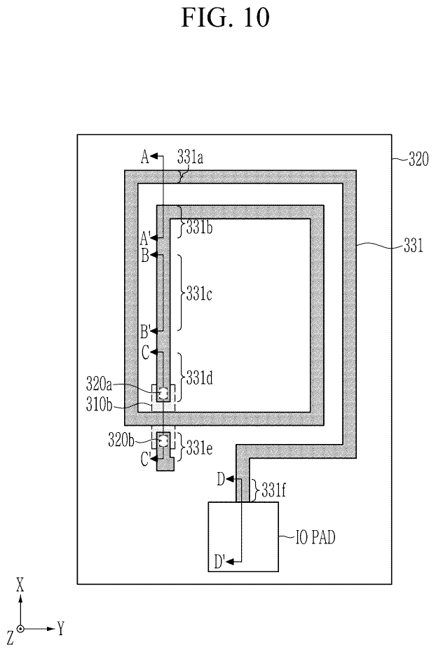

FIG. 10 is a top plan view illustrating an example of an inductor wire.

Referring to FIG. 10, the semiconductor memory device may include an inductor wire. In some implementations, the inductor wire 331 may correspond to the first inductor L1 and the second inductor L2 described referring to FIG. 1 to FIG. 7.

In some implementations, the inductor wire 331 may be positioned on the insulation layer 320. In some implementations, the insulation layer 320 may be a layer including a first contact via 320a and a second contact via 320b. In some implementations, the inductor wire 331 may be connected to the input/output pad IO PAD. In some implementations, the inductor wire 331 may be connected to the first metal wire 310b via the first contact via 320a and the second contact via 320b. The first metal wire 310b may be positioned under the insulation layer 320. In some implementations, among the first to sixth inductor wires 331a to 331f, the fourth inductor wire 331d may be connected to the first metal wire 310b through the first contact via 320a, and the fifth inductor wire 331e may be connected to the first metal wire 310b through the second contact via 320b.

In some implementations, the inductor wire 331 may extend in a direction X and a direction Y. In some implementations, the inductor wire 331 may be arranged in a spiral shape on the same plane. In some implementations, the inductor wire 331 may be arranged in a spiral shape in the opposite clockwise direction from the input/output pad IO PAD to the second contact via 320b.

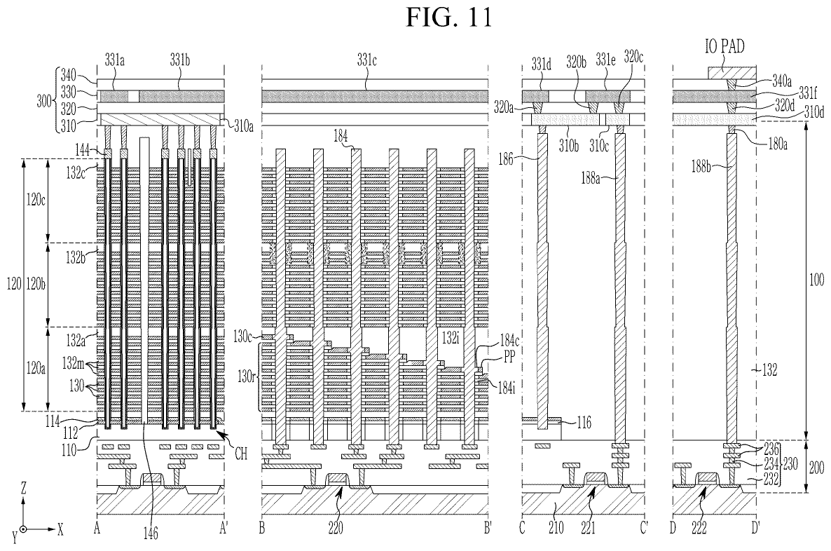

FIG. 11 is a cross-sectional view illustrating an example of a semiconductor memory device including an inductor wire.

FIG. 11 may be a cross-sectional view of the semiconductor memory device 1100 taken along lines A-A′, B-B′, C-C′, and D-D′ of FIG. 10.

Referring to FIG. 11, the semiconductor memory device may include a cell structure 100, a ferry structure 200, a first substrate 210, a wire structure 300, and an input/output pad IO PAD.

In some implementations, the ferry structure 200 may be positioned on the first substrate 210. In some implementations, the ferry structure 200 may include the voltage generator 1120, the row decoder 1130, the page buffer group 1140, and the control logic 1160 of FIG. 1. In some implementations, the ferry structure 200 may include the main transmitter 1151, the equalization transmitter 1152, and the capacitor C_AC of FIG. 2.

In some implementations, the ferry structure 200 may include first to third circuits 220, 221, and 222. In some implementations, the second circuit 221 may be connected to the second metal wire 310c through the first penetration plug 188a and the contact via 180a of the cell structure 100. In some implementations, the second circuit 221 may include an equalization transmitter 1152 of FIG. 2 and a capacitor C_AC connected to the equalization transmitter 1152. In some implementations, the equalization transmitter 1152 of the second circuit 221 may output the equalization data signal, and the capacitor C_AC of the second circuit 221 and the first to sixth inductor wires 331a to 331f of the third wiring layer 330 may output the resonant data signal that resonates the equalization data signal. In some implementations, the resonant data signal may be provided to the input/output pad IO PAD through the fifth contact via 340a of the fourth wiring layer 340.

In some implementations, the third circuit 222 may be connected to the third metal wire 310d via the second penetration plug 188b and the contact via 180a of the cell structure 100. In some implementations, the third circuit 222 may include the main transmitter 1151 of FIG. 2. In some implementations, the third circuit 222 may output the main data signal. In some implementations, the main data signal may be provided to the input/output pad IO PAD via the cell structure 100 and the wire structure 300.

In some implementations, the cell structure 100 may be positioned on the ferry structure 200. In some implementations, the cell structure 100 may include memory cells.

In some implementations, the wire structure 300 may be positioned on the cell structure 100. In some implementations, the wire structure 300 may include a first wiring layer 310, a second wiring layer 320, a third wiring layer 330, and a fourth wiring layer 340.

In some implementations, the first wiring layer 310 may be positioned on the cell structure 100. In some implementations, the first wiring layer 310 may include a bit line 310a and metal wires 310b, 310c, and 310d. In some implementations, the bit line 310a may be connected to the channel pad 144 via the contact via 180a of the cell structure 100.

In some implementations, the first metal wire 310b may be connected to the source contact part 186 via the contact via 180a of the cell structure 100. In some implementations, the first metal wire 310b may be connected to the fourth inductor wire 331d and the fifth inductor wire 331e through the first contact via 320a and the second contact via 320b of the second wiring layer 320.

In some implementations, the second metal wire 310c may be connected to the first penetration plug 188 a through the contact via 180a of the cell structure 100. In some implementations, the second metal wire 310c may be connected to the fifth inductor wire 331e through the third contact via 320c of the second wiring layer 320.

In some implementations, the third metal wire 310d may be connected to the second penetration plug 188 b through the contact via 180a of the cell structure 100. In some implementations, the third metal wire 310d may be connected to the sixth inductor wire 331f via the fourth contact via 320d of the second wiring layer 320.

In some implementations, the second wiring layer 320 may be positioned above the first wiring layer 310. In some implementations, the second wiring layer 320 may include contact vias 320a, 320b, 320c, and 320d. In some implementations, the second wiring layer 320 may correspond to the insulation layer 320 of FIG. 10.

In some implementations, the first contact via 320a may be connected to the first metal wire 310b and the fourth inductor wire 331d. In some implementations, the second contact via 320b may be connected to the first metal wire 310b and the fifth inductor wire 331e. In some implementations, the third contact via 320c may be connected to the second metal wire 310c and the fifth inductor wire 331e. In some implementations, the fourth contact via 320d may be connected to the third metal wire 310d and the sixth inductor wire 331f.

In some implementations, the third wiring layer 330 may be positioned above the second wiring layer 320. The third wiring layer 330 may include the inductor wire 331 of FIG. 10. In some implementations, the inductor wire 331 may include first to sixth inductor wires 331a to 331f.

In some implementations, the fourth inductor wire 331d may be connected to the first contact via 320a. In some implementations, the fifth inductor wire 331e may be connected to the second contact via 320b and the third contact via 320c. In some implementations, the sixth inductor wire 331f may be connected to the fourth contact via 320d. In some implementations, the sixth inductor wire 331f may be connected to the input/output pad IO PAD through the fifth contact via 340a of the fourth wiring layer 340.

In some implementations, the fourth wiring layer 340 may be positioned above the third wiring layer 330. In some implementations, the fourth wiring layer 340 may include a fifth contact via 340a. The fifth contact via 340a may be connected to the sixth inductor wire 331f and the input/output pad IO PAD.

In some implementations, the input/output pad IO PAD may be positioned on the fourth wiring layer 340.

In some implementations, the ferry structure 200 may include a first wire part 230. The first wire part 230 may be positioned on the first substrate 210. The first wire part 230 may be connected to the third circuit 222. In some implementations, the first wire part 230 may include wiring layers 236 separated by a first insulation layer 232 and connected by the contact vias 234.

In some implementations, the cell structure 100 may include a gate stacking structure 120 and a channel structure CH. In some implementations, the gate stacking structure 120 and the channel structure CH may be positioned on the second substrate 110. In some implementations, the gate stacking structure 120 may include alternately stacked cell insulation layers 132 and gate electrodes 130. The channel structure CH may be formed in a direction crossing the second substrate 110 while passing through the gate stacking structure 120.

In some implementations, the horizontal conductive layers 112 and 114 may be positioned between the second substrate 110 and the gate stacking structure 120. In some implementations, the horizontal conductive layers 112 and 114 may electrically connect the channel structure CH and the second substrate 110. In some implementations, the horizontal insulation layer 116 may be positioned instead of the horizontal conductive layer 112 between the second substrate 110 and the gate stacking structure 120 in some regions of the cell structure 100.

In some implementations, the gate stacking structure 120 may include a plurality of gate stacking structures 120a, 120b, and 120c sequentially stacked on the second substrate 110.

In some implementations, the gate electrode 130 may include a lower gate electrode, a memory cell gate electrode, and an upper gate electrode. The lower gate electrode may be used as a gate electrode of a ground-selective transistor. The memory cell gate electrode may form a memory cell. The upper gate electrode may be used as a gate electrode of a string select transistor.

In some implementations, the cell insulation layer 132 may include an interlayer insulating layer 132m positioned between two adjacent gate electrodes 130 within the plurality of gate stacking structures 120a, 120b, and 120c, and upper insulation layers 132a, 132b, and 132c positioned on the plurality of gate stacking structures 120a, 120b, and 120c, respectively. In some implementations, the cell insulation layer 132 may include a pad insulating part 132i.

In some implementations, the channel pad 144 may be positioned on the channel structure CH. In some implementations, the channel pad 144 may be connected to the bit line 310 a via the contact via 180a.

In some implementations, the gate stacking structure 120 may be partitioned into multiple portions in a plane by a separation structure 146 extending in a direction intersecting the second substrate 110 (e.g., a direction Z) and penetrating the gate stacking structure 120. In some implementations, the gate stacking structure 120 partitioned by the separation structure 146 may form one memory block.

In some implementations, the gate contact part 184 may be connected to the gate electrode 130 through the gate stacking structure 120 and electrically connected to the ferry structure 200. In some implementations, the gate contact part 184 may be electrically connected to a connection gate electrode 130c having a pad portion PP among a plurality of gate electrodes 130 included in the gate stacking structure 120, and may be insulated from the remaining gate electrodes 130r with an insulating pattern 184i therebetween.

In some implementations, the pad portion PP may be positioned at the end of the connection gate electrode 130c. In some implementations, the gate contact part 184 may penetrate the pad portion PP of the connection gate electrode 130c and be connected to the inner surface of the pad portion PP. In some implementations, the gate contact part 184 may have a connection part 184c that protrudes toward the inner surface of the pad portion PP and is in direct contact with the pad portion PP.

In some implementations, the source contact part 186 may penetrate the cell insulation layer 132 and be electrically connected to the horizontal conductive layer 112, and 114, and the second substrate 110. Penetration plugs 188a and 188b may penetrate the gate stacking structure 120 or be positioned outside the gate stacking structure 120 to be electrically connected to the first wire part 230 of the ferry structure 200.

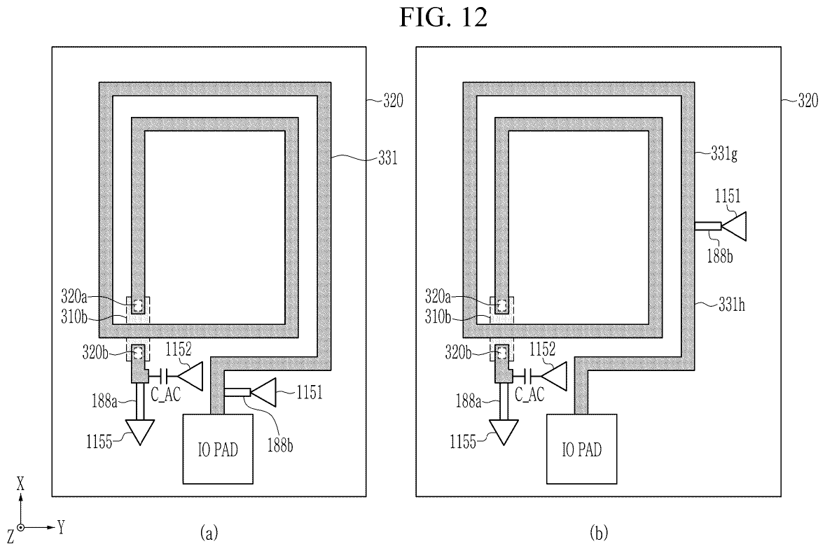

FIG. 12 is a view illustrating an example of a connection relationship of a main transmitter, an equalization transmitter, a receiver, and an inductor wire.

Referring to FIG. 12 (a), the inductor wire 331 may be positioned on the second wiring layer 320 corresponding to the insulation layer. In some implementations, the inductor wire 331 may be connected to the first capacitor C_AC, the equalization transmitter 1152, and the receiver 1155 through contact vias 320a, and 320b, and the first metal wire 310b. In some implementations, the inductor wire 331 may be connected to the receiver 1155 via the first penetration plug 188a. In some implementations, the capacitor C_AC, the equalization transmitter 1152, and the receiver 1155 may be included in the second circuit 221 of FIG. 11.

In some implementations, the inductor wire 331 may be connected to the input/output pad IO PAD. In some implementations, the inductor wire 331 may be connected to the main transmitter 1151 via the second penetration plug 188b. In some implementations, the main transmitter 1151 may be included in the third circuit 222 of FIG. 11.

Referring to FIG. 12 (b), the inductor wire 331 may include a seventh inductor wire 331g and an eighth inductor wire 331h. In some implementations, the seventh inductor wire 331g may be an inductor wire connected from the first penetration plug 188a to the second penetration plug 188b. In some implementations, the seventh inductor wire 331g may correspond to the first inductor L1 of FIG. 4.

In some implementations, the eighth inductor wire 331h may be an inductor wire connected from the input/output pad IO PAD to the second penetration plug 188b. In some implementations, the seventh inductor wire 331h may correspond to the second inductor L2 of FIG. 4.

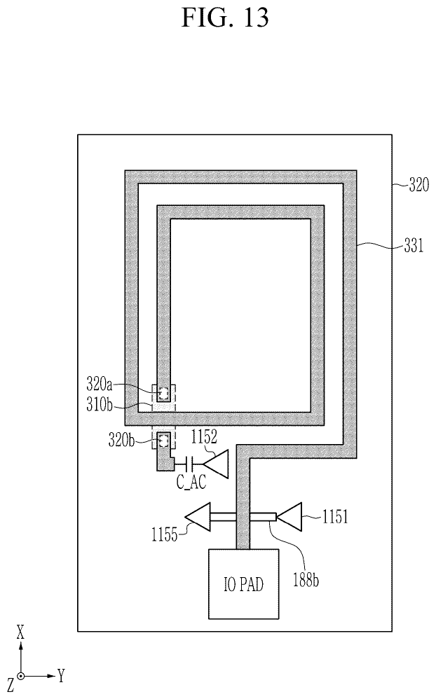

FIG. 13 is a view illustrating an example of a connection relationship of a main transmitter, an equalization transmitter, a receiver, and an inductor wire.

Referring to FIG. 13, the inductor wire 331 may be connected to a capacitor C_AC and an equalization transmitter 1152 via contact vias 320a, and 320b and a first metal wire 310b. In some implementations, the second circuit 222 of FIG. 11 may include the capacitor C_AC and the equalization transmitter 1152.

In some implementations, the inductor wire 331 may be connected to the main transmitter 1151 and the receiver 1155 via the second penetration plug 188b. In some implementations, the third circuit 223 of FIG. 11 may include a main transmitter 1151 and a receiver 1155.

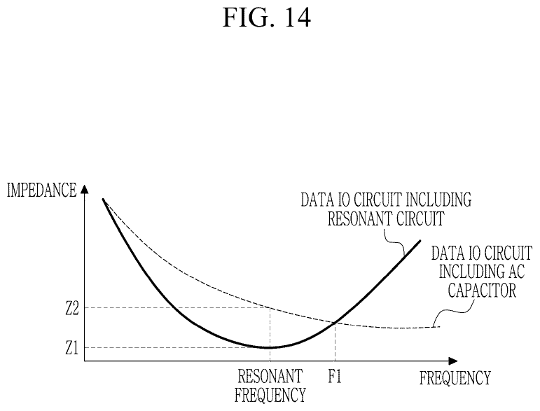

FIG. 14 is a view to explain an example of an impedance depending on a frequency.

In FIG. 14, a horizontal axis of the graph represents a frequency of an equalization data signal SIG_EQ, and a vertical axis of the graph represents an impedance of the capacitor C_AC or an impedance of the capacitor C_AC and the first inductor L1.

Referring to FIG. 2 and FIG. 14, in the data input/output circuit including only the capacitor C_AC between the equalization transmitter 1152 and the first node ND1, the impedance of the capacitor C_AC may gradually decrease as the frequency increases.

In some implementations, in the data input/output circuit including the resonant circuit 1153 including the capacitor C_AC and the first inductor L1 between the equalization transmitter 1152 and the first node ND1, the impedance of the capacitor C_AC and the first inductor L1 may be reduced to a value less than the impedance of the capacitor C_AC until the frequency becomes substantially the same as the resonant frequency.

In some implementations, if the frequency of the equalization data signal SIG_EQ is equal to or lower than the resonant frequency, the impedance of the capacitor C_AC and the first inductor L1 may be lower than the impedance of the capacitor C_AC.

In some implementations, at the resonant frequency, the impedance of the capacitor C_AC and the first inductor L1 may be a first impedance Z1, and the impedance of the capacitor C_AC may be a second impedance Z2 which is greater than the first impedance Z1.

In some implementations, if the frequency of the equalization data signal SIG_EQ corresponds to the first frequency F1 which is higher than the resonant frequency, the impedance of the capacitor C_AC and the first inductor L1 may be the same as the impedance of the capacitor C_AC. If the frequency of the equalization data signal SIG_EQ is higher than the first frequency F1, the impedance of the capacitor C_AC and the first inductor L1 may be greater than the impedance of capacitor C_AC.

In some implementations, if the impedance of the capacitor C_AC and the first inductor L2 is less than the impedance of the capacitor C_AC, the magnitude of the data signal output by the data input/output circuit including the resonant circuit 1153 may be greater than the data signal output by the data input/output circuit including only the capacitor C_AC.

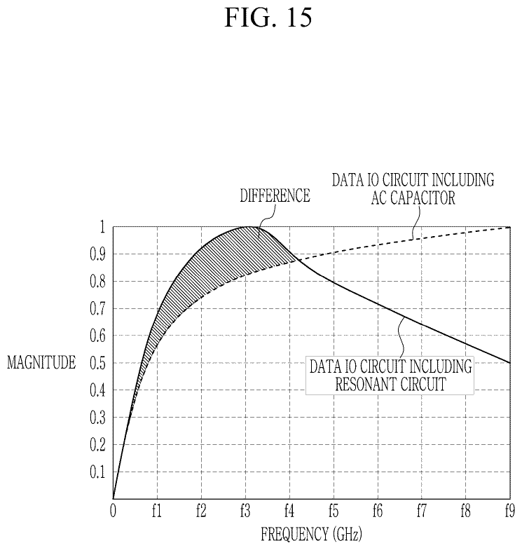

FIG. 15 is a view to explain an example of a magnitude of an output data signal depending on a frequency.

In FIG. 15, a horizontal axis of the graph represents the frequency of the equalization data signal SIG_EQ, and a vertical axis of the graph represents the magnitude of the data signal.

Referring to FIG. 2 and FIG. 15, the magnitude of the data signal of the data input/output circuit including only the capacitor C_AC may gradually increase as the frequency of the equalization data signal SIG_EQ increases.

In some implementations, the magnitude of the data signal of the data input/output circuit including the resonant circuit 1153 may be increased to a value greater than the magnitude of the data signal of the data input/output circuit including only the capacitor C_AC until the frequency of the equalization data signal SIG_EQ becomes substantially the same as the resonant frequency. In some implementations, the third frequency f3 may correspond to the resonant frequency of the resonant circuit 1153.

In some implementations, if the frequency of the equalization data signal SIG_EQ is equal to or lower than the resonant frequency, the magnitude of the data signal of the data input/output circuit including the resonant circuit 1153 may be greater than the magnitude of the data signal of the data input/output circuit including only the capacitor C_AC. In some implementations, at the third frequency f3, the magnitude of the data signal of the data input/output circuit including only the capacitor C_AC may be “0.82”, and the magnitude of the data signal of the data input/output circuit including the resonant circuit 1153 may be “1”.

In some implementations, if the frequency of the equalization data signal SIG_EQ corresponds between the second frequency f2 and the fourth frequency f4, the magnitude of the data signal of the data input/output circuit including the resonant circuit 1153 may be greater than the magnitude of the data signal of the data input/output circuit including only the capacitor C_AC. In some implementations, the frequency range of the output data signal output by the data input/output circuit including the resonant circuit 1153 may correspond between the second frequency f2 and the fourth frequency f4.

In some implementations, if the frequency of the equalization data signal SIG_EQ is higher than the resonant frequency, the magnitude of the data signal of the data input/output circuit including the resonant circuit may gradually decrease.

In some implementations, if the frequency of the equalization data signal SIG_EQ corresponds between the fourth frequency f4 and the fifth frequency f5, the magnitude of the data signal of the data input/output circuit including the resonant circuit 1153 may be smaller than the magnitude of the data signal of the data input/output circuit including only the capacitor C_AC.

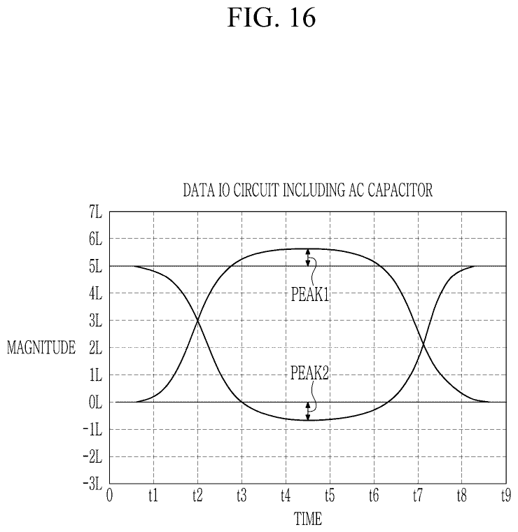

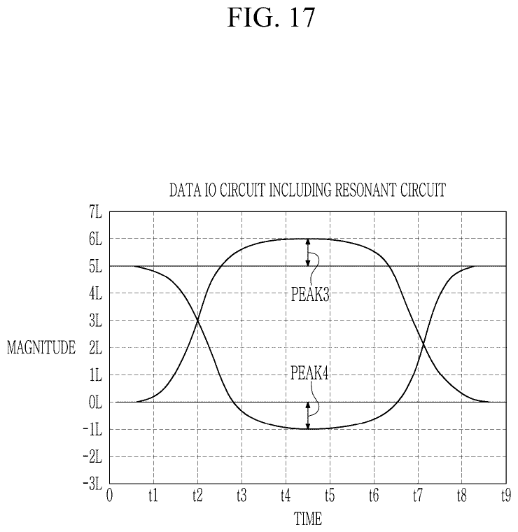

FIG. 16 and FIG. 17 are views for explaining an example of a peak value of an output data signal.

In FIG. 16 and FIG. 17, a horizontal axis of the graph represents a time, and a vertical axis of the graph represents a magnitude of the output data signal SIG_OUT.

Referring to FIG. 2 and FIG. 16, the data input/output circuit including only the capacitor C_AC may output the output data signal of a high level or a low level. In some implementations, the high level may correspond to a fifth level 5L, and the low level may correspond to a zeroth level 0L.

In some implementations, the data input/output circuit including only the capacitor C_AC may output a first output data signal and output a second output data signal subsequent to the first output data signal.

In some implementations, the data input/output circuit including only the capacitor C_AC may output the first output data signal at the low level and the second output data signal at the high level. In some implementations, the magnitude of the second output data signal of the high level may be higher than the fifth level 5L due to the coupling of the capacitor C_AC. In some implementations, the magnitude of the high level second output data signal may increase by a first peak value (PEAK1) at the fifth level 5L due to the coupling of the capacitor C_AC.

In some implementations, the data input/output circuit including only the capacitor C_AC may output the first output data signal of the high level and the second output data signal of the low level. In some implementations, the magnitude of the second output data signal of the low level may be lower than the zero level due to the coupling of the capacitor C_AC. In some implementations, the magnitude of the second output data signal of the low level may be reduced by a second peak value PEAK2 from the zero level 0L due to the coupling of the capacitor C_AC.

Referring to FIG. 2 and FIG. 17, the data input/output circuit including the resonant circuit 1153 may output a third output data signal and may output a fourth output data signal subsequent to the third output data signal.

In some implementations, the data input/output circuit including the resonant circuit 1153 may output the third output data signal of the low level and the fourth output data signal of the high level. In some implementations, the fourth output data signal of the high level may be higher than the fifth level 5L by the resonant circuit 1153. In some implementations, the magnitude of the fourth output data signal of the high level may be increased by a third peak value PEAK3 at the fifth level 5L by the resonant circuit 1153. In some implementations, the third peak value PEAK3 may be greater than the first peak value PEAK1.

In some implementations, the magnitude by which the output data signal of the high level is increased by the resonant circuit 1153 may be larger than the magnitude by which the output data signal of the high level is increased by the capacitor C_AC.

In some implementations, the data input/output circuit including the resonant circuit 1153 may output the third output data signal of the high level and the fourth output data signal of the low level. In some implementations, the fourth output data signal of the low level may be lowered than the fifth level 5L by the resonant circuit. In some implementations, the magnitude of the fourth output data signal of the low level may be reduced by the fourth peak value PEAK4 from the zero level 0L by the resonant circuit. In some implementations, the fourth peak value PEAK4 may be greater than the second peak value PEAK2.

In some implementations, the magnitude by which the output data signal of the low level is reduced by the resonant circuit 1153 may be greater than the magnitude by which the output data signal of the low level is reduced by the capacitor C_AC.

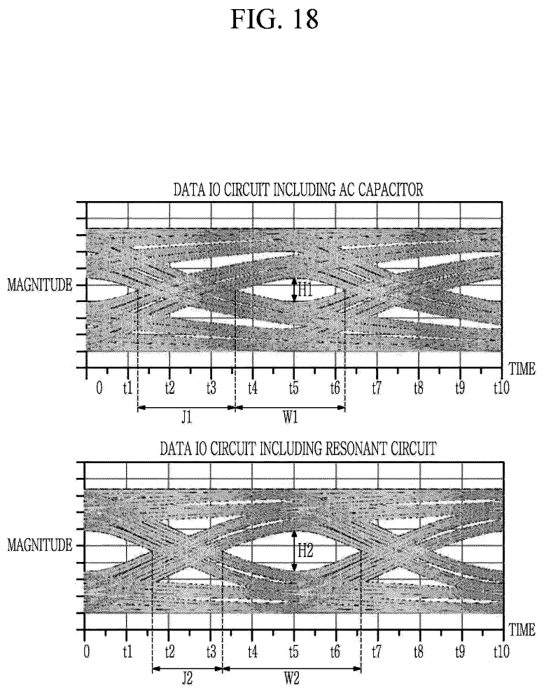

FIG. 18 is a view to explain an example of an eye diagram of an output data signal.

In FIG. 18, a horizontal axis of the graph represents a time, and a vertical axis of the graph represents a magnitude of the output data signal SIG_OUT.

Referring to FIG. 2 and FIG. 18, a jitter value of the output data signal output by the data input/output circuit including only the capacitor C_AC may be a first jitter J1. In some implementations, the jitter value of the output data signal output by the data input/output circuit including the resonant circuit 1153 may be a second jitter J2 that is smaller than the first jitter J1. In some implementations, the output data signal output by the data input/output circuit including the resonant circuit 1153 may take a shorter time to transition from the low level to the high level or from the high level to the low level than the output data signal output by the data input/output circuit including only the capacitor C_AC.

In some implementations, an eye height value of the output data signal output by the data input/output circuit including only the capacitor C_AC may be a first height H1. In some implementations, the eye height value of the output data signal output by the data input/output circuit including the resonant circuit 1153 may be a second height H2 greater than the first height H1.

In some implementations, an eye width value of the output data signal output by the data input/output circuit including only the capacitor C_AC may be a first width W1. In some implementations, the eye width value of the output data signal output by the data input/output circuit including the resonant circuit 1153 may be a second width W2, which is larger than the first width W1.

In some implementations, the magnitude of the output data signal output by the data input/output circuit including the resonant circuit 1153 may be greater than the magnitude of the output data signal output by the data input/output circuit including only the capacitor C_AC.

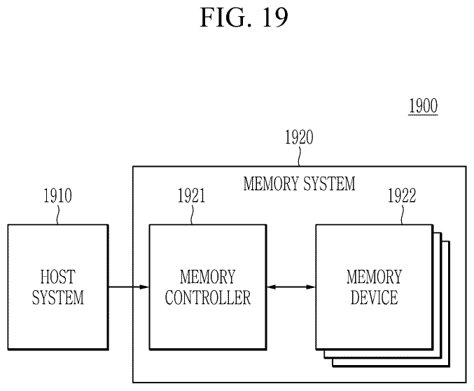

FIG. 19 is a view explaining an example of a memory system.

Referring to FIG. 19, an electron system 1900 may include a host system 1910 and a memory system 1920. The host system 1910 and the memory system 1920 may communicate through an interface, and the memory system 1920 may include a memory controller 1921 and memory devices 1922.

In some implementations, the host system 1910 and the memory system 1920 may communicate a data through a serial advanced technology attachment (SATA) interface, a universal serial bus (USB) interface, a peripheral component interconnect express (PCIe) interface, a non-volatile memory express (NVMe) interface, and a universal flash storage (UFS) interface, a double data rate (DDR) interface, etc.

In some implementations, the memory system 1920 may be implemented as a solid state drive (SSD), a universal flash storage (UFS), an embedded SSD (eSSD), a multimedia card (MMC), or an embedded multimedia card (eMMC).

In some implementations, the memory controller 1921 may control the memory devices 1922 in response to a request received from the host system 1910. In some implementations, the memory controller 1921 may include the data input/output circuit 1150 of FIG. 1. In some implementations, the memory controller 1921 may provide the output data signal that is the sum of the resonant data signal that resonates the equalization data signal and the main data signal to the host system 1910 or the memory devices 1922.

In some implementations, the memory devices 1922 may be a volatile memory or a non-volatile memory. In some implementations, the memory devices 1922 may include the data input/output circuit 1150 of FIG. 1. In some implementations, the memory devices 1922 may provide the output data signal that is the sum of the resonant data signal that resonates the equalization data signal and the main data signal to the memory controller 1921.

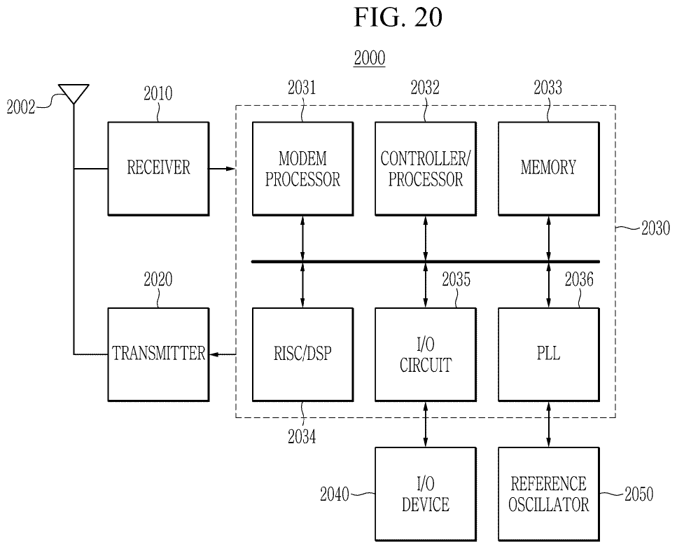

FIG. 20 is a drawing for explaining an example of a communication apparatus.

Referring to FIG. 20, a communication apparatus 2000 may include an antenna 2002, a receiver 2010, a transmitter 2020, a communication module 2030, an input/output device 2040, and a reference oscillator 2050. The receiver 2010 may provide a data signal received from an outside through the antenna 2002 to the communication module 2030. The transmitter 2020 may convert the data signal received from the communication module 2030 into an analog signal and then output it to the outside through antenna 2002. In some implementations, the transmitter 2020 may output the output data signal that is the sum of the resonant data signal that resonates the equalization data signal and the main data signal.

In some implementations, the communication module 2030 may include a modem processor 2031, a controller/processor 2032, a memory 2033, a RISC/DSP 2034, an input/output circuit 2035, and a phase locked loop 2036.

In some implementations, the modem processor 2031 may perform processing operations such as encoding, a modulation, a demodulation, and a decoding for a data transmission and data reception. The controller/processor 2032 may control blocks within the communication module 2030.

In some implementations, the memory 2033 may store data and various instruction codes. The RISC/DSP 2034 may perform general or specialized processing operations in the communication apparatus 2000.

In some implementations, the input/output circuit 2035 may communicate with the external input/output device 2040. The input/output circuit 2035 may include the data input/output circuit 1150 of FIG. 1. The input/output circuit 2035 may output the output data signal that is the resonant data signal that resonates the equalization data signal and the main data signal to the external input/output device 2040.

In some implementations, the phase locked loop 2036 may perform a frequency modulation operation using a frequency signal received from the reference oscillator 2050. The reference oscillator 2050 may be implemented as an XO (crystal oscillator), a VCXO (voltage controlled crystal oscillator), or a TCXO (temperature compensated crystal oscillator). The communication module 2030 may perform processing operations required for a communication by using output signals generated from the phase locked loop 2036.

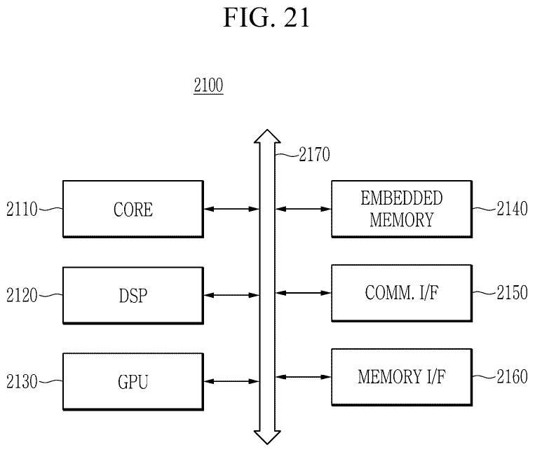

FIG. 21 is a view illustrating an example of a system on chip.

Referring to FIG. 21, a system-on-chip (SoC) 2100 may refer to an IC that integrates components of a computing system or other electronic system. For example, as one of the system-on-chip 2100, an application processor (AP) may include a processor and components for other functions.

In some implementations, the system-on-chip 2100 may include a core 2110, a digital signal processor (DSP) 21920, a graphic processing unit (GPU) 2130, an embedded memory 2140, a communication interface 2150, and a memory interface 2160. Components of the system-on-chip 2100 may communicate with each other via a bus 2170.

In some implementations, the core 2110 may process instructions and control the operation of the components included in the system-on-chip 2100. For example, the core 2110 may drive an operating system and execute applications on the operating system by processing a series of instructions. The DSP 2120 may generate useful data by processing digital signals, for example, digital signals provided from the communication interface 2150. The GPU 2130 may generate data for an image to be output through a display device from an image data provided from the embedded memory 2140 or the memory interface 2160, or may encode the image data. The embedded memory 2140 may store data required for the core 2110, the DSP 2120, and the GPU 2130 to be operated. The memory interface 2160 may provide an interface to an external memory, for example, a dynamic random access memory (DRAM), a flash memory, etc., of the system-on-chip 2100.

In some implementations, the communication interface 2150 may provide a serial communication with the outside of the system-on-chip 2100. For example, the communication interface 2150 may connect to an ethernet and may include SerDes for a serial communication.

In some implementations, the data input/output circuit 1150 of FIG. 1 may be included in the communication interface 2150 and the memory interface 2160. Specifically, the communication interface 2150 or the memory interface 2160 may output the output data signal that is the sum of the resonant data signal that resonates the equalization data signal and the main data signal.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While this disclosure has been described in connection with some implementations, it is to be understood that the disclosure is not limited to the disclosed implementations, but, on the contrary, is intended to cover various modifications and equivalent arrangements included within the spirit and scope of the appended claims.

What is claimed is:

1. A semiconductor device comprising:
an input/output pad connected to a first node;
a main transmitter configured to provide a main data signal to the input/output pad through the first node;
an equalization transmitter configured to provide an equalization data signal to the input/output pad through the first node; and
a resonant circuit including a first capacitor and a first inductor, wherein the first capacitor and the first inductor are coupled in series between the first node and the equalization transmitter.

2. The semiconductor device of claim 1, wherein the resonant circuit is configured to receive the equalization data signal and output, via resonance, a resonant data signal to the first node.

3. The semiconductor device of claim 1, wherein a frequency of the equalization data signal and a resonant frequency of the resonant circuit are substantially the same.

4. The semiconductor device of claim 1, wherein the resonant circuit comprises a second inductor connected between the first node and the input/output pad.

5. The semiconductor device of claim 1, wherein the equalization transmitter is configured to output the equalization data signal based on a rising edge or a falling edge of the main data signal.

6. The semiconductor device of claim 1, comprising:
a substrate;
a ferry structure on the substrate, wherein the ferry structure comprises the main transmitter, the first capacitor, and the equalization transmitter;
a cell structure on the ferry structure, wherein the cell structure comprises a plurality of memory cells; and
a wire structure on the cell structure, wherein the wire structure comprises the first inductor.

7. The semiconductor device of claim 6, wherein the input/output pad is on the wire structure and is connected to the first inductor through a contact via.

8. The semiconductor device of claim 1, wherein
the equalization transmitter comprises an equalization capacitor, and
a capacitance of the first capacitor is larger than a capacitance of the equalization capacitor.

9. The semiconductor device of claim 1, comprising:
a delay circuit configured to delay the equalization data signal.

10. The semiconductor device of claim 1, comprising:
a first resistor connected between the main transmitter and the first node; and
a second resistor connected between the equalization transmitter and the first node.

11. The semiconductor device of claim 1, comprising:
a receiver connected to a second node between the first capacitor and the first inductor.

12. A semiconductor circuit comprising:
a main transmitter configured to provide a main data signal to a first node;
an equalization transmitter configured to output an equalization data signal;
a resonant circuit configured to receive the equalization data signal and output, via resonance, a resonant data signal to the first node; and
an input/output pad connected to the first node and configured to output the main data signal and the resonant data signal.

13. The semiconductor circuit of claim 12, wherein the resonant circuit includes:
a first capacitor connected between the main transmitter and the first node; and
a first inductor connected between the first capacitor and the first node, wherein the first inductor and the first capacitor are coupled in series.

14. The semiconductor circuit of claim 13, wherein the resonant circuit comprises a second inductor connected between the first node and the input/output pad.

15. The semiconductor circuit of claim 12, wherein the equalization transmitter is configured to provide the equalization data signal at a high level or a low level on a rising edge or a falling edge of the main data signal, respectively.

16. The semiconductor circuit of claim 12, wherein a frequency of the equalization data signal is within a 3 dB bandwidth of a bandpass bandwidth of the resonant circuit.

17. A semiconductor device comprising:
a substrate;
a ferry structure on the substrate, wherein the ferry structure comprises a main transmitter, an equalization transmitter, and a capacitor connected to the equalization transmitter;
a cell structure on the ferry structure, wherein the cell structure comprises a plurality of memory cells;
a wire structure on the cell structure, wherein the wire structure comprises an inductor wire connected to the capacitor and the main transmitter; and
an input/output pad on the wire structure, wherein the input/output pad is connected to the inductor wire.

18. The semiconductor device of claim 17, wherein the capacitor and the inductor wire are configured to
receive an equalization data signal from the equalization transmitter, and
output, via resonance, a resonant data signal.

19. The semiconductor device of claim 18, wherein the resonant data signal is configured to be at a high level or a low level at a rising edge or a falling edge of a main data signal output by the main transmitter, respectively.

20. The semiconductor device of claim 18, wherein
the main transmitter is configured to output a main data signal, and
the input/output pad is configured to output an output data signal that is a sum of the main data signal and the resonant data signal.
